(19) United States
(12) Patent Application Publication
(10) Pub. No.: US 2022/0157674 A1
(43) Pub. Date: May 19, 2022

(54) SUBSTRATE STRUCTURE

(71) Applicant: Subtron Technology Co., Ltd., Hsinchu County (TW)

(72) Inventor: Chung Ying Lu, Hsinchu County (TW)

(73) Assignee: Subtron Technology Co., Ltd., Hsinchu County (TW)

(21) Appl. No.: 17/348,741

(22) Filed: Jun. 15, 2021

(30) Foreign Application Priority Data
Nov. 16, 2020 (TW) 109139952

(51) Int. Cl. H01L 23/13; H01L 23/14; H01L 23/15; H01L 23/498

(52) U.S. Cl. CPC H01L 23/13; H01L 23/145; H01L 23/49838; H01L 23/49827; H01L 23/15

(57) ABSTRACT

A substrate structure includes a substrate, a first metal layer, a second metal layer, and a third metal layer. The substrate has a first surface and a second surface opposite to each other and at least one through hole. The first metal layer is disposed on the first surface of the substrate. The second metal layer is disposed on the second surface of the substrate. The third metal layer is disposed on an inner wall of the at least one through hole of the substrate and connects the first metal layer and the second metal layer. The third metal layer and a portion of the first metal layer define at least one containing cavity, and the at least one containing cavity is configured to contain solder to fix the substrate structure onto an external circuit.

### CROSS-REFERENCE TO RELATED APPLICATION

This application claims the priority benefit of Taiwan application serial no. 109139952, filed on Nov. 16, 2020. The entirety of the above-mentioned patent application is hereby incorporated by reference herein and made a part of this specification.

### BACKGROUND

### Technical Field

The disclosure relates to a substrate structure, and in particular, relates to a substrate structure including a containing cavity defined by metal layers and configured to contain solder.

### Description of Related Art

Generally, the holes (also called as soldering holes) on the circuit substrate configured to contain excessive solder are defined by the solder mask layer. That is, these holes are made of a solder mask material. Nevertheless, since the solder mask material is formed by ink, its material property is relatively brittle. Further, in a circuit substrate with a thin thickness, since the thickness of the solder mask layer is not thick enough to resist the film flow caused by the packaging adhesive during packaging, the adhesive resist function is not provided as a result. In addition, as the solder mask material and the solder are poorly joined, the joining strength provided by the solder of the circuit substrate in the following process may thus be affected.

### SUMMARY

The disclosure provides a substrate structure including a containing cavity (or called as a soldering hole) defined by metal layers and exhibiting a favorable adhesive resist function and a strengthened joining force provided by solder.

The disclosure provides a substrate structure including a substrate, a first metal layer, a second metal layer, and a third metal layer. The substrate has a first surface and a second surface opposite to each other and at least one through hole. The first metal layer is disposed on the first surface of the substrate. The second metal layer is disposed on the second surface of the substrate. The third metal layer is disposed on an inner wall of the at least one through hole of the substrate and connects the first metal layer and the second metal layer. The third metal layer and a portion of the first metal layer define at least one containing cavity, and the at least one containing cavity is configured to contain solder to fix the substrate structure onto an external circuit.

In an embodiment of the disclosure, a diameter of the containing cavity is between 80 microns and 100 microns.

In an embodiment of the disclosure, the substrate structure further includes an adhesive layer disposed on the first surface of the substrate and located between the first metal layer and the substrate.

In an embodiment of the disclosure, the first metal layer has at least one opening, and the at least one opening exposes a portion of the adhesive layer.

In an embodiment of the disclosure, the second metal layer has a plurality of openings, and the openings expose portions of the second surface of the substrate.

In an embodiment of the disclosure, the substrate structure further includes a solder mask layer disposed on the second metal layer, filling at least one of the openings, and contacting the second surface of the substrate.

In an embodiment of the disclosure, a material of the first metal layer, a material of the second metal layer, and a material of the third metal layer are identical.

In an embodiment of the disclosure, the substrate is an insulating rigid substrate.

In an embodiment of the disclosure, a material of the insulating rigid substrate includes a polymer glass fiber composite material, glass, or ceramics.

In an embodiment of the disclosure, a thickness of the substrate structure is greater than 80 microns and less than 100 microns.

To sum up, in the design of the substrate structure provided by the disclosure, the containing cavity containing the solder configured to fix the substrate structure onto an external circuit is defined by the first metal layer and the third metal layer. That is, the material of the containing cavity is metal, and metal provides favorable ductility and malleability. Therefore, compared to the related art through which a solder mask material is used to act as a soldering hole, a good adhesive resist function is provided by the substrate structure of the disclosure thanks to the arrangement of the containing cavity. Besides, the soldering area may be expanded, and the joining force provided by the solder may also be strengthened.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional schematic view of a portion of a substrate structure according to an embodiment of the disclosure.

### DESCRIPTION OF THE EMBODIMENTS

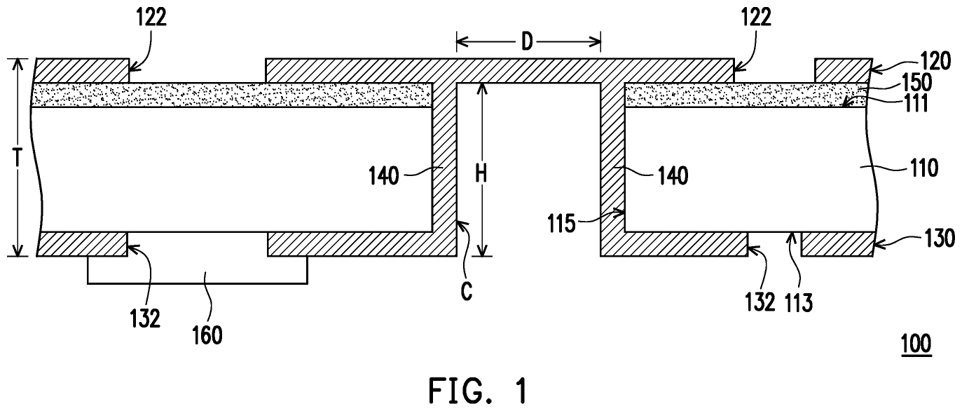

FIG. 1 is a cross-sectional schematic view of a portion of a substrate structure according to an embodiment of the disclosure. With reference to FIG. 1, in this embodiment, a substrate structure 100 includes a substrate 110, a first metal layer 120, a second metal layer 130, and a third metal layer 140. The substrate 110 has a first surface 111 and a second surface 113 opposite to each other and at least one through hole (one through hole 115 is schematically shown). The first metal layer 120 is disposed on the first surface 111 of the substrate 110. The second metal layer 130 is disposed on the second surface 113 of the substrate 110. The third metal layer 140 is disposed on an inner wall of the through hole 115 of the substrate 110 and connects the first metal layer 120 and the second metal layer 130. The third metal layer 140 and a portion of the first metal layer 120 define at least one containing cavity C, and the containing cavity C is configured to contain solder to fix the substrate structure 100 onto an external circuit. Herein, the external circuit may be, but not limited to, a driving circuit board or a printed circuit board, for example.

To be specific, in this embodiment, the substrate 110 is, for example, an insulating rigid substrate. A material of the insulating rigid substrate is, for example, a polymer glass fiber composite material, glass, ceramics, or other suitable insulating rigid substrates. The through hole 115 penetrates through the substrate 110 and connects the first surface 111 and the second surface 113 of the substrate 110. Moreover, the substrate structure 100 provided by this embodiment further includes an adhesive layer 150. The adhesive layer 150 is disposed on the first surface 111 of the substrate 110 and is located between the first metal layer 120 and the substrate 110. The first metal layer 120 may be fixed onto the first surface 111 of the substrate 110 through the adhesive layer 150. Herein, the adhesive layer 150 is an adhesive material exhibiting reduced moisture absorption, low overflowing, good heat resistance, and favorable adhesion, to adhere the first metal layer 120 and the substrate 110 together to form a solder resist structure.

With reference to FIG. 1 again, the first metal layer 120 provided by this embodiment has at least one opening (a plurality of openings 122 are schematically shown), and the openings 122 expose portions of the adhesive layer 150. Moreover, the second metal layer 130 has a plurality of openings 132, and the openings 132 expose portions of the second surface 113 of the substrate 110. The third metal layer 140 covers the inner wall of the through hole 115 and a peripheral surface of the adhesive layer 150 and extends to connect the first metal layer 120 and the second metal layer 130.

As shown in FIG. 1, a portion of the first metal layer 120 may be treated as a bottom portion of the containing cavity C, and the third metal layer 140 may be treated as a side wall of the containing cavity C. Herein, a top-view shape of the containing cavity C is, but not limited to, circular. A material of the first metal layer 120, a material of the second metal layer 130, and a material of the third metal layer 140 are substantially identical and are preferably be, but not limited to, copper layers, for example. Further, in this embodiment, a diameter D of the containing cavity C is between, for example, 80 microns and 100 microns, and a depth H of the containing cavity C is equal to, for example, a length of the third metal layer 140.

Besides, the substrate structure 100 provided by this embodiment further includes a solder mask layer 160. The solder mask layer 160 is disposed on the second metal layer 130, fills at least one of the openings 132, and contacts the second surface 113 of the substrate 110. Herein, the solder mask layer 160 exposes a portion of the second metal layer 130. Further, a material of the solder mask layer 160 is different from the material of the first metal layer 120, the material of the second metal layer 130, and the material of the third metal layer 140. Preferably, a thickness T of the substrate structure 100 provided by this embodiment is greater than 80 microns and less than 100 microns, meaning that the substrate structure 100 is implemented as a thin substrate structure.

In applications, this substrate structure 100 may be electrically connected to, for example, a thin light-emitting diode packaging structure or other active devices and/or passive devices. When singulation is performed to cut the substrate structure 100, the substrate structure 100 may be divided into two or four independent substrate units from the containing cavity C.

In short, the containing cavity C provided by this embodiment is defined by a portion of the first metal layer 120 and the third metal layer 140. As such, through eutectic bonding provided between the metal materials and the solder, a soldering area is expanded, and a joining force provided by the solder is also increased. Further, since an expanded soldering area is provided owning to the arrangement of the containing cavity C, enhanced reliability is provided in the following packaging process. In addition, in the related art, a solder mask material is used to act as a soldering hole, but in the present embodiment, the substrate structure 100 exhibits a good adhesive resist function thanks to ductility and malleability provided by the arrangement of the containing cavity C.

In view of the foregoing, in the design of the substrate structure provided by the disclosure, the containing cavity containing the solder configured to fix the substrate structure onto an external circuit is defined by the first metal layer and the third metal layer. That is, the material of the containing cavity is metal, and metal provides favorable ductility and malleability. Therefore, compared to the related art through which a solder mask material is used to act as a soldering hole, a good adhesive resist function is provided by the substrate structure of the disclosure thanks to the arrangement of the containing cavity. Besides, the soldering area may be expanded, and the joining force provided by the solder may also be strengthened.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A substrate structure, comprising:
a substrate, having a first surface and a second surface opposite to each other and at least one through hole;
a first metal layer, disposed on the first surface of the substrate;
a second metal layer, disposed on the second surface of the substrate; and
a third metal layer, disposed on an inner wall of the at least one through hole of the substrate, connecting the first metal layer and the second metal layer, wherein the third metal layer and a portion of the first metal layer define at least one containing cavity, and the at least one containing cavity is configured to contain solder to fix the substrate structure onto an external circuit.

2. The substrate structure according to claim 1, wherein a diameter of the at least one containing cavity is between 80 microns and 100 microns.

3. The substrate structure according to claim 1, further comprising:
an adhesive layer, disposed on the first surface of the substrate, located between the first metal layer and the substrate.

4. The substrate structure according to claim 3, wherein the first metal layer has at least one opening, and the at least one opening exposes a portion of the adhesive layer.

5. The substrate structure according to claim 1, wherein the second metal layer has a plurality of openings, and the openings expose portions of the second surface of the substrate.

6. The substrate structure according to claim 5, further comprising:
a solder mask layer, disposed on the second metal layer, filling at least one of the openings, contacting the second surface of the substrate.

7. The substrate structure according to claim 1, wherein a material of the first metal layer, a material of the second metal layer, and a material of the third metal layer are identical.

8. The substrate structure according to claim 1, wherein the substrate is an insulating rigid substrate.

9. The substrate structure according to claim 8, wherein a material of the insulating rigid substrate comprises a polymer glass fiber composite material, glass, or ceramics.

10. The substrate structure according to claim 1, wherein a thickness of the substrate structure is greater than 80 microns and less than 100 microns.
